(19) United States
(12) Patent Application Publication
(10) Pub. No.: US 2026/0217521 A1
(43) Pub. Date: Jul. 30, 2026

(54) MICRO-ELECTRO MECHANICAL SYSTEM MICROPHONE

(71) Applicant: AAC Technologies Pte. Ltd., Singapore (SG)

(72) Inventor: Euan James Boyd, EB (GB)

(21) Appl. No.: 19/037,294

(22) Filed: Jan. 27, 2025

(51) Int. Cl. B81B 3/00; H04R 19/04

(52) U.S. Cl. CPC B81B 3/0072; H04R 19/04; B81B 2201/0257; B81B 2203/0127; B81B 2203/0307; B81B 2203/0315; H04R 2201/003

(57) ABSTRACT

An MEMS microphone comprises a substrate comprising a back cavity, a back plate fixed to the substrate, and a diaphragm arranged therebetween along a thickness direction of the substrate. The diaphragm comprises a vibration main section comprising an inner region, an outer region and a plurality of connecting portions spaced apart along a circumference direction of the diaphragm. The inner region is suspended above the back cavity. The outer region is fixedly connected to the substrate. The connecting portion is suspended above the substrate. Along a radial direction of the diaphragm, two ends of the connecting portion are fixedly connected to the inner region and the outer region. A width of the connecting portion decreases along a direction from the inner region towards the outer region. The MEMS microphone reduces improves the sensitivity of the MEMS microphone, and the stress on the connecting portion is evenly distributed.

### TECHNICAL FIELD

The present disclosure relates to the technical field of microphones, and in particular to an Micro-Electro Mechanical System (MEMS) microphone.

### BACKGROUND

A Micro-Electro Mechanical System (MEMS) microphone has advantages of a small size, high temperature resistance, and easy installation, thereby being widely used in mobile phones, tablet computers, and smart wearable devices. An MEMS microphone includes a diaphragm, and the diaphragm usually adopts a cantilever beam structure, that is, the diaphragm comprises an inner region and an outer region spaced apart from each other. The inner region is suspended above a substrate, the outer region is fixedly connected to the substrate, and the inner region is connected to the outer region through a connecting portion of the cantilever beam structure.

For an MEMS microphone in the prior art, the stiffness of the connecting portion is reduced and the sensitivity of the diaphragm is improved by reducing a width of the connecting portion or increasing a space between adjacent connecting portions. However, under a high-loading condition, such a structure may lead to a high stress concentration at an inner end of the connecting portion, easily causing failure of the connecting portion.

Therefore, it needs to provide a new MEMS microphone to solve the above-mentioned problems.

### SUMMARY

The present disclosure provides a MEMS microphone, capable of balancing the stress on the connecting portion and improving the stress uniformity.

In an aspect, an embedment of the present disclosure provides a micro-electro mechanical system (MEMS) microphone, comprising: a substrate comprising a back cavity extending therethrough; a back plate fixed to the substrate; and a diaphragm provided between the back plate and the substrate along a thickness direction of the substrate. The diaphragm comprises a vibration main section; the vibration main section comprises an inner region, an outer region and a plurality of connecting portions spaced apart along a circumference direction of the diaphragm; and the inner region is suspended above the back cavity; the outer region is fixedly connected to the substrate. The connecting portion is suspended above the substrate; and along a radial direction of the diaphragm, two ends of the connecting portion are fixedly connected to the inner region and the outer region. A width of the connecting portion decreases along a direction from the inner region towards the outer region.

In an improved embodiment, the width of the connecting portion is within a range from 5 μm to 20 μm.

In an improved embodiment, the connecting portion includes a first end connected to the inner region and a second end connected to the outer region, and the width D1 of the first end and the width D2 of the second end satisfy 1.1≤D1:D2≤1.3.

In an improved embodiment, a plurality of the connecting portions are arranged at equal angles around an axis of the substrate.

In an improved embodiment, the number of the connecting portions is within a range from 60 to 100.

In an improved embodiment, the outer region is fixedly connected to the substrate through a first anchor structure; and along the thickness direction of the substrate, two side surfaces of the first anchor structure are fixedly connected to the outer region and the substrate.

In an improved embodiment, along the radial direction of the diaphragm, a gap is formed between the first anchor structure and the connecting portion, so that at least a portion of the outer region is suspended over the substrate.

In an improved embodiment, the diaphragm further comprises a plurality of fixed sections, which are fixedly connected to the substrate and/or the back plate; along the circumference direction of the diaphragm, each of plurality of the fixed sections is located between two adjacent connecting portions; and each of the plurality of fixed sections is spaced apart from the connecting portion, the inner region and the outer region.

In an improved embodiment, each of the plurality of fixed sections is fixedly connected to only the substrate; or each of the plurality of fixed sections is fixedly connected to only the back plate through a second anchor structure; or each of the plurality of fixed sections is fixedly connected to both the substrate and the back plate through a second anchor structure.

It is to be understood that the foregoing general description and the following detailed description are exemplary only and are not intended to limit the present disclosure.

### BRIEF DESCRIPTION OF DRAWINGS

FIG. 1 is a schematic diagram of a structure of an MEMS microphone according to an embodiment of the present disclosure;

FIG. 2 is a cross-sectional view along AA′ of the MEMS microphone shown in FIG. 1;

FIG. 3 is a schematic diagram of a structure of the MEMS microphone shown in FIG. 2 provided with a back plate;

FIG. 4 is a schematic diagram of a partial structure of a vibration main section shown in FIG. 1; and

FIG. 5 is a cross-sectional view along BB′ of the MEMS microphone shown in FIG. 1.

### REFERENCE NUMERALS

1—substrate
   10—back cavity
2—back plate
3—diaphragm
   3a—vibration main section
   3b—fixed section
   31—inner region
   32—outer region
   33—connecting portion
      331—first end
      332—second end
4—first anchor structure
5—second anchor structure
6—gap

It is to be understood that the foregoing general description and the following detailed description are exemplary only and are not intended to limit the present disclosure.

### DESCRIPTION OF EMBODIMENTS

The present disclosure will be described below in combination with the embodiments and accompanying drawings.

The terms used in the embodiments of the present disclosure are merely for the purpose of describing particular embodiments but not intended to limit the present disclosure. Unless otherwise noted in the context, the singular form expressions “a”, “an”, “the” and “said” used in the embodiments and appended claims of the present disclosure are also intended to represent plural form expressions thereof.

It should be understood that the term “and/or” used herein is merely an association relationship describing associated objects, indicating that there may be three relationships, for example, A and/or B may indicate that three cases, i.e., A existing individually, A and B existing simultaneously, B existing individually. In addition, the character “/” herein generally indicates that the related objects before and after the character form an “or” relationship.

It should be noted that, the expressions such as “upper”, “lower”, “left”, “right” and the like mentioned in embodiments of the present disclosure are described with reference to the placement status in the accompanying drawings, and should not be construed as limiting embodiments of the present disclosure. In addition, it should also be understood that, in the context, while referring to an element being formed “above” or “below” another element, it is possible that the element is directly formed “above” or “below” the other element, it is also possible that the element is formed “above” or “below” the other element via an intermediate element.

An embodiment of the present disclosure provides an MEMS microphone, which can be applied to electronic devices such as cellphones, smart watches, tablet computers, laptops, virtual reality devices or walkie-talkies. The MEMS microphone may be, for example, a capacitive microphone, a piezoelectric microphone or an optical microphone.

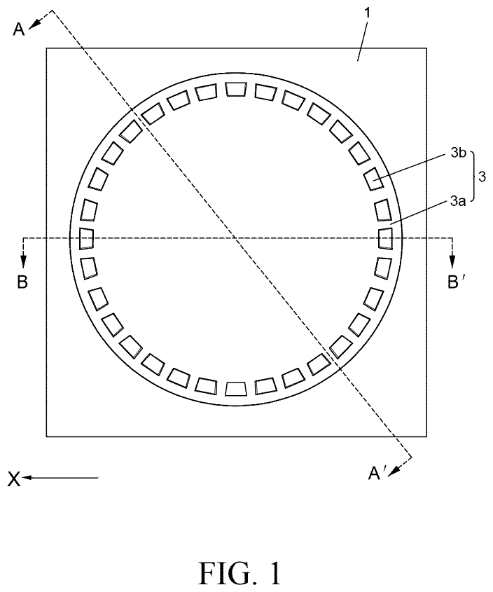

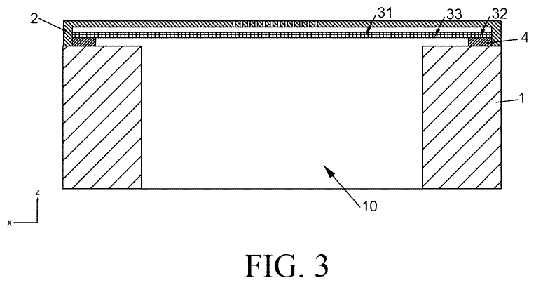

As shown in FIG. 1 to FIG. 3, the MEMS microphone at least includes a substrate 1, a back plate 2 and a diaphragm 3. The substrate 1 is provided with a back cavity 10 running therethrough. The back plate 2 is fixed to the substrate 1 and is spaced apart from the diaphragm 3, and can form a capacitance system with the diaphragm 3. The diaphragm 3 is located between the back plate 2 and the substrate 1 in a thickness direction of the substrate 1. When the diaphragm 3 vibrates, a distance between the diaphragm 3 and the back plate 2 changes accordingly, thereby causing a change in terms of the capacitance. The back plate 2 may have a structure shown in FIG. 3, or other structures. The embodiments of the present disclosure do not limit the structure of the back plate 2, or a connection manner of the back plate 2 and the substrate 1.

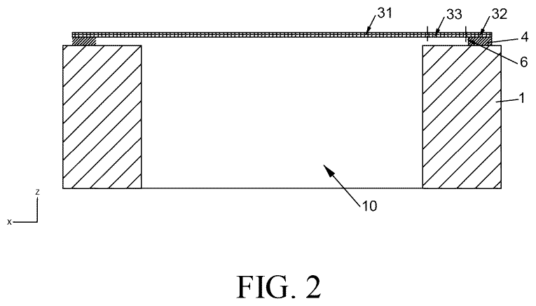

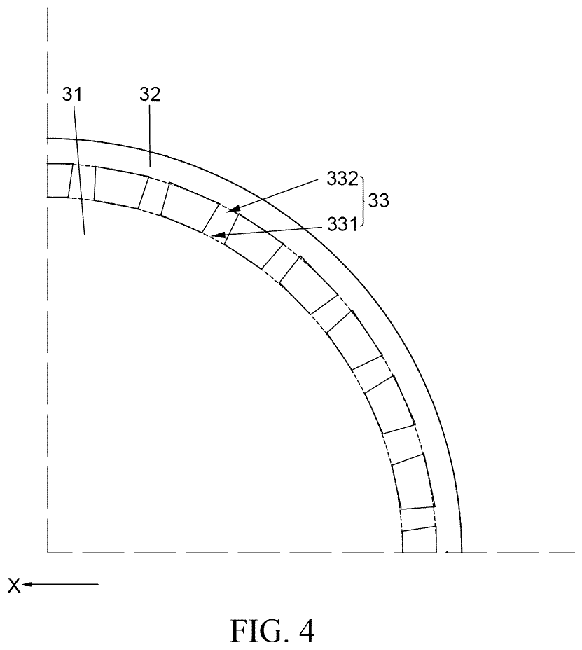

As shown in FIG. 2 and FIG. 4, the diaphragm 3 includes a vibration main section 3a. The vibration main section 3a includes an inner region 31, an outer region 32 and a plurality of connecting portions 33 spaced apart from one another along a circumference of the diaphragm 3. The inner region 31 is suspended above the back cavity 10, that is, a projection of the inner region 31 onto the substrate 1 along the thickness direction Z of substrate 1 is located within the back cavity 10. The outer region 32 is fixedly connected to the substrate 1. The connecting portion 33 is suspended above the substrate 1. Along a radial direction X of the diaphragm 3, two ends of the connecting portion 33 are fixedly connected to the inner region 31 and the outer region 32, respectively. In this embodiment, the inner region 31 of the diaphragm 3 is completely suspended above the substrate 1, only the outer region 32 of the diaphragm 3 is connected to the substrate 1, and the inner region 31 is connected to the outer region 32 by a plurality of connecting portions 33 which are spaced apart from one another and suspended above the substrate 1. Such a structure can improve the flexibility of the diaphragm 3, thereby increasing the amplitude, so that the displacement change of the diaphragm 3 under an action of an external sound pressure can be increased. In this way, it is conducive to improving the sensitivity of the MEMS microphone and improving the accuracy of the MEMS microphone in terms of converting sound signals into electrical signals.

The connecting portion 33 includes a first end 331 connected to the inner region 31 and a second end 332 connected to the outer region 32. A width of the connecting portion 33 gradually decreases along a direction from the first end 331 towards the second end 332. Compared with a structure of the connecting portion 33 having a same width, the above-mentioned structure (i.e., a width of the connecting portion 33 gradually decreasing along a direction from the first end 331 towards the second end 332) can reduce an amount of material required for forming the connecting portion 33, which is conducive to reducing the rigidity of the connecting portion 33, to increase the amplitude of the diaphragm 3, thereby facilitating the improvement of the sensitivity of the MEMS microphone. Moreover, compared with a structure in which the second end 332 has a large width and the first end 331 has a small width, the connecting portion 33 in this embodiment has the largest width at an end connected to the inner region 31 (i.e., the first end 331) and the smallest width at another end connected to the outer region 32 (i.e., the second end 332), which can disperse the stress to the outer region 32, thereby reducing the internal stress at the first end 331, reducing the maximum stress on the connecting portion 33 under a given load, and thus avoiding the first end 331 from being damaged due to excessive stress.

Therefore, by configuring the connecting portion 33 to have a structure in which the width of the connecting portion 33 gradually decreases along the direction from the first end 331 towards the second end 332, the sensitivity of the diaphragm 3 can be improved while the stresses on various portions of the connecting portion 33 can be balanced to avoid stress concentration, so that the connecting portion 33 can withstand a higher load and the structural stability of the connecting portion 33 can be improved, thereby improving the structural stability of the MEMS microphone and the reliability of the MEMS microphone during a fall or bump, and thus improving a service life of the MEMS microphone.

In an example, along the direction from the first end 331 towards the second end 332, the width of the connecting portion 33 may change evenly, so that compared with a structure with a step-like change or other uneven changes, the evenly changing structure has a better effect of dispersing the stress.

In an embodiment, the width of the first end 331 is D1 and the width of the second end 332 is D2, where a ratio of D1 to D2 shall satisfy: 1.1≤D1:D2≤1.3. For example, the ratio of D1 to D2 may be 1.1, 1.12, 1.15, 1.18, 1.2, 1.22, 1.25, 1.27 or 1.3, or other value within the above-mentioned range, which is not limited in this embodiment. When the width D1 of the first end 331 and the width D2 of the second end 332 satisfy the above-mentioned range, the structural rationality of the connecting portion 33 can be ensured, thereby avoiding that the width of the first end 331 is too large and that the width of the second end 332 is too small.

In an embodiment, the width of any portion of the connecting portion 33 shall be within a range from 5 μm to 20 μm, for example, may be 5 μm, 6 μm, 8 μm, 10 μm, 12 μm, 15 μm, 17 μm, 19 μm or 20 μm, or other value within the above-mentioned range, which is not limited in this embodiment. Then, the width D1 of the first end 331 shall be smaller than 20 μm and the width D2 of the second end 332 shall be greater than 5 μm. When the width of any portion of the connecting portion 33 satisfies the above-mentioned range, it can ensure that the connecting portion 33 has sufficient structural strength as a whole, and avoid the reduction of the amplitude of the diaphragm 3 due to the excessive area of the connecting portion 33.

In an embodiment, a plurality of connecting portions 33 are arranged at equal angles around an axis of the substrate 1, that is, the plurality of connecting portions 33 are evenly distributed in a circumferential direction of the substrate 1, so that the stress can be evenly dispersed in the circumferential direction of the substrate 1. The even distribution of the plurality of connecting portions 33 in the circumferential direction of the substrate 1 is also conducive to improving the connection stability between the inner region 31 and the outer region 32, thereby improving the structural stability of the diaphragm 3. Alternatively, the plurality of connecting portions 33 may be unevenly distributed in the circumferential direction of the substrate 1, which is not limited in this embodiment.

The number of the connecting portions 33 may be within a range from 60 to 100, for example, may be 60, 65, 70, 75, 80, 85, 90, 95 or 100, or other value within the above-mentioned range, which is not limited in this embodiment. When the number of the connecting portions 33 satisfies the above-mentioned range, the stress on a single connecting portion 33 can be reduced, and the structural stability of the connecting portion 33 can be improved, which is beneficial to improving the effect of dispersing the stress from the inner region 31 to the outer region 32, and is also beneficial to improving the connection stability between the inner region 31 and the outer region 32, thereby improving the structural stability of the diaphragm 3.

In an embodiment, as shown in FIG. 3, the outer region 32 is fixedly connected to the substrate 1 through a first anchor structure 4. Along the thickness direction Z of the substrate 1, two side surfaces of the first anchor structure 4 are respectively fixedly connected to the outer region 32 and the substrate 1. In an example, the first anchor structure 4 can be an oxide layer, which can ensure that the outer region 32 is firmly connected to the substrate 1, and provide a certain support for the diaphragm 3, thereby improving the stability of the diaphragm 3 under high load, so as to extend the reliability and the service life of the diaphragm 3. It should be noted that, the first anchor structure 4 may also be a connection structure in other forms, which shall not be limited in this embodiment.

In an example, as shown in FIG. 2, along a radial direction X of the diaphragm 3, a gap 6 is formed between the first anchor structure 4 and the connecting portion 33, so that at least a portion of the outer region 32 is suspended over the substrate 1, that is, the second end 332 is not in contact with the first anchor structure 4, thereby reducing a risk of stress concentration at the second end 332.

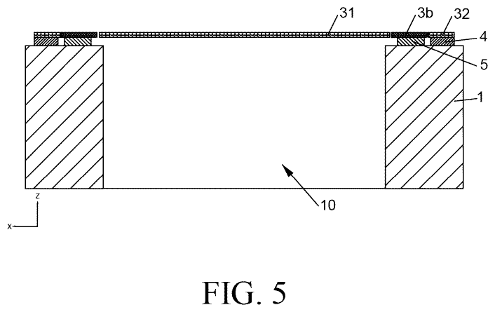

In an embodiment, as shown in FIG. 1 and FIG. 5, the diaphragm 3 may further include a plurality of fixed sections 3b, which are fixedly connected to the substrate 1 and/or the back plate 2. In an example, along the circumference direction of the diaphragm 3, any fixed section 3b is arranged between two adjacent connecting portions 33, and the fixed section 3b is spaced apart from the connecting portion 33, the inner region 31 and the outer region 32, that is, the fixed section 3b is separated from the vibration main section 3a and does not vibrate up and down together with the vibration main section 3a. By the arrangement of the fixed section 3b, the internal and external pressures of the diaphragm 3 can be balanced without affecting the vibration effect of the vibration main section 3a, thereby improving the mechanical stability of the diaphragm 3 and helping to extend the service life of the MEMS microphone. The fixed section 3b is fixedly connected to the substrate 1 and/or the back plate 2 through a second anchor structure 5. The second anchor structure 5 may be an oxide layer identical to the first anchor structure 4, or may be a connection structure in other forms, which shall not be limited in this embodiment.

The fixed section 3b in this embodiment may be formed by etching the diaphragm 3. For example, for a structure in which the fixed section 3b is fixedly connected to the substrate 1 through a second anchor structure 5: a layer of oxide is deposited on the substrate 1 to form a first anchor structure 4 and a second anchor structure 5, then the diaphragm 3 is provided on the layer of the oxide, and then the diaphragm 3 is etched according to a preset pattern to form the vibration main section 3a and the fixed section 3b that are independent of each other.

The above description merely illustrates some embodiments of the present disclosure. It should be noted that those skilled in the art may make improvements without departing from a creative concept of the present disclosure, and all these improvements shall fall into a protection scope of the present disclosure.

What is claimed is:

1. A micro-electro mechanical system (MEMS) microphone, comprising:
a substrate comprising a back cavity extending therethrough;
a back plate fixed to the substrate; and
a diaphragm provided between the back plate and the substrate along a thickness direction of the substrate,
wherein the diaphragm comprises a vibration main section; the vibration main section comprises an inner region, an outer region and a plurality of connecting portions spaced apart along a circumference direction of the diaphragm; and the inner region is suspended above the back cavity; the outer region is fixedly connected to the substrate;
wherein the connecting portion is suspended above the substrate; and along a radial direction of the diaphragm, two ends of the connecting portion are fixedly connected to the inner region and the outer region; and
wherein a width of the connecting portion decreases along a direction from the inner region towards the outer region.

2. The MEMS microphone as described in claim 1, wherein the width of the connecting portion is within a range from 5 μm to 20 μm.

3. The MEMS microphone as described in claim 1, wherein the connecting portion includes a first end connected to the inner region and a second end connected to the outer region, and the width D1 of the first end and the width D2 of the second end satisfy 1.1≤D1:D2≤1.3.

4. The MEMS microphone as described in claim 1, wherein a plurality of the connecting portions are arranged at equal angles around an axis of the substrate.

5. The MEMS microphone as described in claim 1, wherein the number of the connecting portions is within a range from 60 to 100.

6. The MEMS microphone as described in claim 1, wherein the outer region is fixedly connected to the substrate through a first anchor structure; and along the thickness direction of the substrate, two side surfaces of the first anchor structure are fixedly connected to the outer region and the substrate.

7. The MEMS microphone as described in claim 6, wherein along the radial direction of the diaphragm, a gap is formed between the first anchor structure and the connecting portion, so that at least a portion of the outer region is suspended over the substrate.

8. The MEMS microphone as described in claim 1,
wherein the diaphragm further comprises a plurality of fixed sections, which are fixedly connected to the substrate and/or the back plate; along the circumference direction of the diaphragm, each of plurality of the fixed sections is located between two adjacent connecting portions; and each of the plurality of fixed sections is spaced apart from the connecting portion, the inner region and the outer region.

9. The MEMS microphone as described in claim 8, wherein each of the plurality of fixed sections is fixedly connected to only the substrate; or each of the plurality of fixed sections is fixedly connected to only the back plate through a second anchor structure; or each of the plurality of fixed sections is fixedly connected to both the substrate and the back plate through a second anchor structure.
